(19) United States
(12) Patent Application Publication
(10) Pub. No.: US 2025/0208260 A1
(43) Pub. Date: Jun. 26, 2025

(54) ATTACHMENT STRUCTURE OF EXTERNAL ENVIRONMENT SENSOR AND VEHICLE INCLUDING THE SAME

(71) Applicant: HONDA MOTOR CO., LTD., Tokyo (JP)

(72) Inventors: Akira FUJITA, Tokyo (JP); Hiromasa TAGUCHI, Tokyo (JP); Mari TAKEUCHI, Tokyo (JP)

(21) Appl. No.: 18/916,980

(22) Filed: Oct. 16, 2024

(30) Foreign Application Priority Data
Dec. 20, 2023 (JP) 2023-215095

(51) Int. Cl. G01S 7/481; G01S 17/931

(52) U.S. Cl. CPC G01S 7/4813; G01S 17/931

(57) ABSTRACT

An attachment structure of an external environment sensor is arranged on a roof of a vehicle. The attachment structure includes, an external environment sensor, a mounting portion on which the external environment sensor is mounted, and a cover arranged over the external environment sensor. A front portion of the cover is provided with a first air flow opening that connects an internal space of the cover and an external space of the cover, a rear portion of the cover is provided with a second air flow opening that connects the internal space of the cover and the external space of the cover, and the internal space of the cover is provided with an air flow passage that connects the first air flow opening and the second air flow opening.

### TECHNICAL FIELD

The present invention relates to an attachment structure of an external environment sensor mounted on a vehicle and the vehicle including the same.

### BACKGROUND ART

In recent years, efforts have been actively made to provide access to sustainable transportation systems that take into account people in vulnerable situations among traffic participants. To achieve this, research and development for further improving safety and convenience of traffic through development of preventive safety technologies is attracting attention. For example, US Patent Application Publication No. 2022/0212609 discloses a sensor (an external environment sensor) attached to a roof of a vehicle via a bracket.

The external environment sensor described in US Patent Application Publication No. 2022/0212609 is arranged on the roof of the vehicle, and is therefore susceptible to the effects of direct sunlight, which makes an ambient temperature of the external environment sensor likely to increase. Accordingly, the external environment sensor is likely to receive the thermal load.

### SUMMARY OF THE INVENTION

In view of the above background, an object of the present invention is to suppress the thermal load on the external environment sensor by suppressing the increase in the ambient temperature of the external environment sensor, in an attachment structure of the external environment sensor arranged on the roof of the vehicle, and in the vehicle including the attachment structure. This will ultimately contribute to the development of the sustainable transportation systems.

To achieve such an object, one aspect of the present invention provides an attachment structure (17) of an external environment sensor arranged on a roof (2) of a vehicle (1), the attachment structure comprising: an external environment sensor (14); a mounting portion (19) on which the external environment sensor is mounted; and a cover (20) arranged over the external environment sensor, wherein a front portion of the cover is provided with a first air flow opening (53) that connects an internal space of the cover and an external space of the cover, a rear portion of the cover is provided with a second air flow opening (55) that connects the internal space of the cover and the external space of the cover, and the internal space of the cover is provided with an air flow passage (57) that connects the first air flow opening and the second air flow opening.

According to this aspect, the first air flow opening and the second air flow opening connect the internal space of the cover to the external space. Accordingly, for example, when the vehicle is traveling, the travel wind caused by the traveling of the vehicle passes through the air flow passage and cools the external environment sensor arranged in the internal space of the cover and the circumference of the external environment sensor. Accordingly, in the attachment structure of the external environment sensor arranged on the roof of the vehicle, the increase in the ambient temperature of the external environment sensor is suppressed, so that the thermal load on the external environment sensor is suppressed.

In the above aspect, preferably, the mounting portion is a roof rail having a main surface facing upward, the roof rail includes a first inclined portion (41) that extends forward with a downward inclination, and the first inclined portion continues from a space below the second air flow opening to a space below the first air flow opening.

According to this aspect, water, which has entered the internal space of the cover from the external space through the first air flow opening or the second air flow opening due to rainfall and the like, is drained along the first inclined portion to the front side of the roof rail. This prevents water from accumulating around the external environment sensor.

In the above aspect, preferably, the roof rail further includes a pair of second inclined portions (42) that extends laterally outward with a downward inclination from the first inclined portion.

According to this aspect, water, which has entered the internal space of the cover from the external space through the first air flow opening or the second air flow opening due to rainfall and the like, is drained along each second inclined portion to the laterally outward space of the roof rail. Accordingly, it is possible to more effectively prevent water from accumulating around the external environment sensor.

In the above aspect, preferably, the vehicle further includes a pair of side rails (4) that extends forward with a downward inclination from a laterally outward space of the roof rail to a hood (9) of the vehicle, and a laterally outward end of each of the second inclined portions is connected to the corresponding side rail.

According to this aspect, water, which has been drained through each second inclined portion to the laterally outward space of the roof rail, is drained onto the hood through the side rail. Accordingly, water, which has been drained to the laterally outward space of the roof rail through each second inclined portion, can be prevented from flowing back to each second inclined portion.

In the above aspect, preferably, each of the side rails defines a groove (59) that continues from the laterally outward space of the roof rail to the hood, and the laterally outward end of each of the second inclined portions is connected to the groove.

According to this aspect, water, which has been drained through each second inclined portion to the laterally outward space of the roof rail, is drained along the groove in the appropriate direction.

In the above aspect, preferably, a front end of the first inclined portion is connected to an upper end of a windshield (8) of the vehicle.

According to this aspect, water, which has been drained to the front of the cover through the first inclined portion, is drained to the front of the windshield along the windshield. Accordingly, it is possible to prevent water, which has been drained to the front of the cover through the first inclined portion, from flowing back to the first inclined portion.

In the above aspect, preferably, the air flow passage extends along a front-and-rear direction from the first air flow opening to the second air flow opening.

According to this aspect, the travel wind passes smoothly through the air flow passage along the front-and-rear direction. Accordingly, the cooling effect on the external environment sensor and its circumference can be improved.

In the above aspect, preferably, the external environment sensor is a LiDAR.

According to this aspect, in the attachment structure of the LiDAR arranged on the roof of the vehicle, the increase in the ambient temperature of the LiDAR is suppressed.

To achieve such an object, one aspect of the present invention provides a vehicle (1) comprising: the attachment structure (17) of the external environment sensor according to the above aspect; a vehicle speed sensor (13) configured to detect a vehicle speed; and a controller (16) connected to the external environment sensor and the vehicle speed sensor, wherein the controller is configured to determine whether the vehicle is stopped based on a detection result of the vehicle speed sensor, and stop operation of the external environment sensor in a case where the controller determines that the vehicle is stopped.

According to this aspect, when the vehicle is stopped and the travel wind is not blowing, the heat generation of the external environment sensor can be suppressed. Accordingly, the increase in the ambient temperature of the external environment sensor is more effectively suppressed.

Thus, according to the above aspects, it is possible to suppress the increase in the ambient temperature of the external environment sensor in the attachment structure of the external environment sensor arranged on the roof of the vehicle, and in the vehicle including the attachment structure.

### BRIEF DESCRIPTION OF THE DRAWING(S)

FIG. 1 is a side view showing a vehicle provided with a sensor attachment structure according to an embodiment;

FIG. 2 is a block diagram showing a plurality of sensors and a controller provided in the vehicle according to the embodiment;

FIG. 3 is a perspective view showing a roof of the vehicle on which the sensor attachment structure according to the embodiment is provided;

FIG. 4 is an exploded perspective view showing a state where a cover is removed from the roof of the vehicle on which the sensor attachment structure according to the embodiment is provided;

FIG. 5 is a sectional side view showing the main portion of the roof of the vehicle on which the sensor attachment structure according to the embodiment is provided;

FIG. 6 is a perspective view showing a roof rail according to the embodiment;

FIG. 7 is a side view showing the roof rail according to the embodiment (a side view seen from the arrow VII side of FIG. 6); and

FIG. 8 is a perspective view showing the main portion of the roof of the vehicle on which the sensor attachment structure according to the embodiment is provided.

### DETAILED DESCRIPTION OF THE INVENTION

Hereinafter, with reference to the drawings, an embodiment of a vehicle 1 provided with an attachment structure of an external environment sensor (hereinafter referred to as a sensor attachment structure 17) according to the present invention will be described. The following description will be given on the basis that the vehicle 1 is on a horizontal plane.

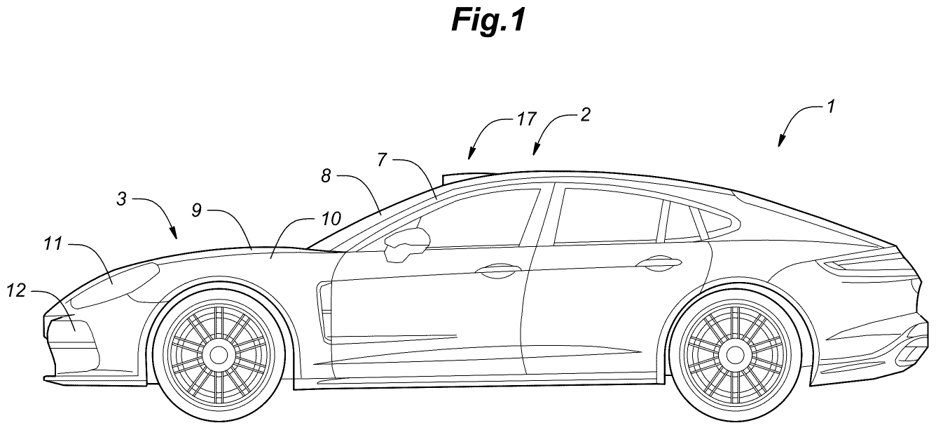

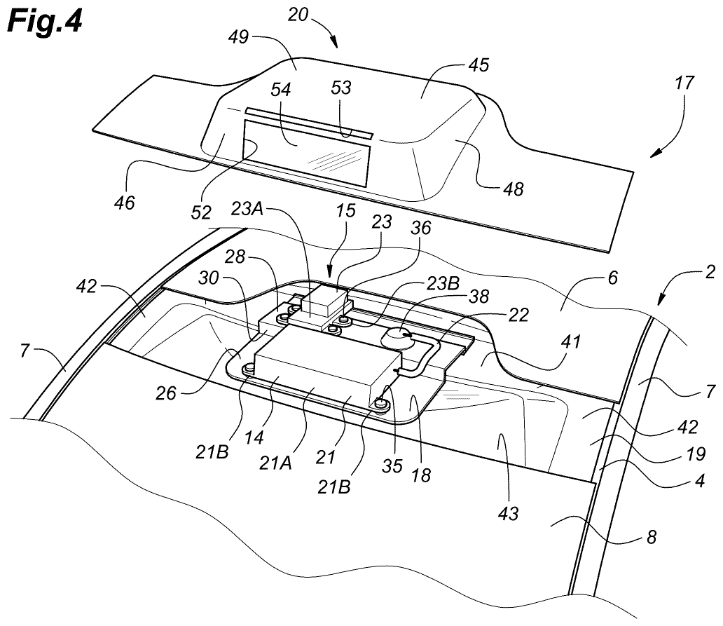

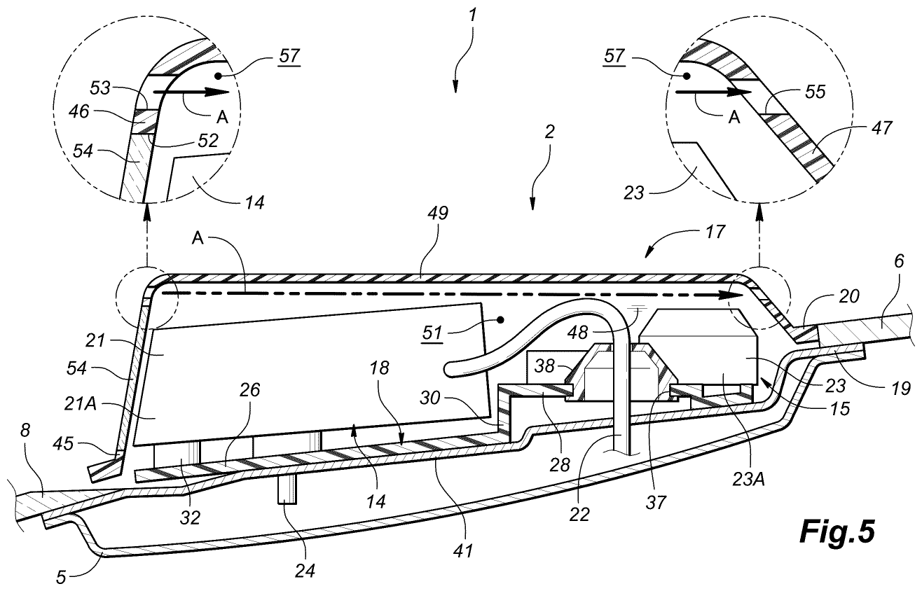

As shown in FIG. 1, the vehicle 1 is, for example, a four-wheeled automobile. The vehicle 1 includes an upper structure 2 (roof) that constitutes the upper portion of the vehicle 1, and a front structure 3 that constitutes the front portion of the vehicle 1. With reference to FIGS. 4 and 5, the upper structure 2 includes a pair of left and right side rails 4 (see FIG. 4) extending in the front-and-rear direction of the vehicle 1 (hereinafter referred to simply as “the front-and-rear direction”), a roof member 5 (see FIG. 5) extending in the lateral direction and stretched over the left and right side rails 4, a roof panel 6 arranged above and behind the roof member 5, and side garnishes 7 respectively arranged over the side rails 4.

In the present embodiment, each side rail 4 is formed in an arch shape with the central portion in the front-and-rear direction curved upward. That is, the front portion of each side rail 4 extends forward with a downward inclination. The roof panel 6 is made of, for example, glass. The roof panel 6 is arranged in the central portion in the front-and-rear direction of the vehicle 1. The front end of the roof panel 6 may be arranged above the rear end of the roof member 5. A windshield 8 is arranged between the front portions of the pair of left and right side rails 4. The windshield 8 extends forward with a downward inclination.

With reference to FIG. 1, the front structure 3 includes, for example, a hood 9, a pair of front fenders 10 arranged laterally outward of the hood 9, and light emitters 11 and a front bumper 12 arranged in front of the hood 9. The hood 9 is arranged in front of the windshield 8. The front portion of each side rail 4 is arranged rearward and laterally outward of the hood 9.

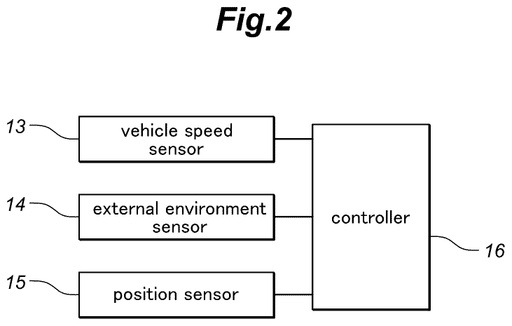

As shown in FIG. 2, the vehicle 1 includes a plurality of sensors for detecting the condition of the vehicle 1 and the condition around the vehicle 1. In the present embodiment, the vehicle 1 includes a vehicle speed sensor 13 that detects the vehicle speed, an external environment sensor 14 for detecting the condition around the vehicle 1, a position sensor 15 that detects the position and direction of the vehicle 1, and a controller 16 connected to the vehicle speed sensor 13, the external environment sensor 14, and the position sensor 15.

The controller 16 includes an arithmetic processing unit (a processor such as a CPU or an MPU) and a storage device (memory such as a ROM or a RAM). The controller 16 may be configured as a single piece of hardware or a unit composed of plural pieces of hardware.

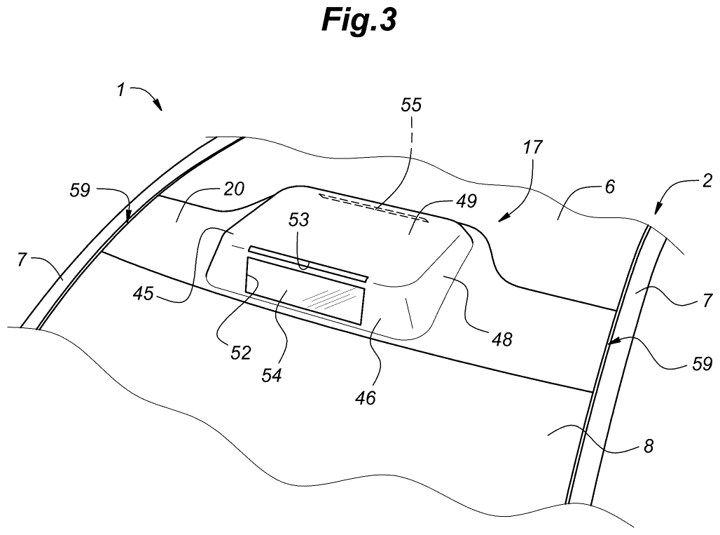

As shown in FIG. 3, the sensor attachment structure 17 is a structure for arranging the external environment sensor 14 on the upper structure 2 (roof) of the vehicle 1. As shown in FIGS. 4 and 5, in the present embodiment, the sensor attachment structure 17 includes the external environment sensor 14, the position sensor 15, a base 18 for fixing the external environment sensor 14 and the position sensor 15, a roof rail 19 (an example of a mounting portion) on which the external environment sensor 14 and the position sensor 15 are mounted via the base 18, and a cover 20 arranged over the external environment sensor 14 and the position sensor 15. In another embodiment, the external environment sensor 14 and the position sensor 15 may be mounted directly on the roof rail 19.

In the present embodiment, the external environment sensor 14 is a Light Detection And Ranging (LiDAR). The LiDAR emits light such as infrared rays to the area around the vehicle 1, and captures the reflected light to detect the relative position of objects around the vehicle 1 with respect to the vehicle 1. The external environment sensor 14 (LiDAR) includes, for example, a light emitting module (not shown), a light receiving module (not shown), a casing 21 that houses the light emitting module and the light receiving module, and a harness 22 connected to the light emitting module and the light receiving module.

The casing 21 of the external environment sensor 14 includes a casing body portion 21A formed in a substantially rectangular parallelepiped shape, and a plurality of protruding pieces 21B extending laterally from the casing body portion 21A. In the present embodiment, two protruding pieces 21B are provided. Each protruding piece 21B is formed in a plate shape. A through hole (not shown) penetrating in the up-and-down direction is formed in each protruding piece 21B.

The position sensor 15 includes, for example, a Global Navigation Satellite System (GNSS) antenna (not shown) and a casing 23 that houses the GNSS antenna. The GNSS antenna receives signals output from the GNSS artificial satellites and detects the current position (latitude, longitude, and altitude) of the vehicle 1. For example, the position sensor 15 may include, as a GNSS antenna, a GPS antenna that receives radio waves from a Global Positioning System (GPS) satellite.

The casing 23 of the position sensor 15 includes a casing body portion 23A formed in a substantially rectangular parallelepiped shape, and a plurality of protruding pieces 23B protruding laterally from the casing body portion 23A. In the present embodiment, two protruding pieces 23B are provided. Each protruding piece 23B is formed in a plate shape. A through hole (not shown) penetrating in the up-and-down direction is formed in each protruding piece 23B.

The base 18 is formed in a plate shape. The base 18 may be fastened to the roof rail 19 by a plurality of bolts 24. Accordingly, the external environment sensor 14 and the position sensor 15 are arranged on the upper structure 2 (roof) of the vehicle 1 via the base 18. The base 18 includes a base front portion 26 that constitutes the front portion of the base 18, a base rear portion 28 that constitutes the rear portion of the base 18 and is arranged higher than the base front portion 26, and a step 30 that connects the base front portion 26 and the base rear portion 28.

The external environment sensor 14 is fixed to the base front portion 26. The base front portion 26 is arranged below the external environment sensor 14. The base front portion 26 extends forward with a downward inclination. As shown in FIG. 5, the upper surface of the base front portion 26 is provided with a plurality of bosses 32 extending upward.

A fastening hole (not shown) is formed in each boss 32. A female screw (not shown) may be formed in the fastening hole. The central axis of the fastening hole of each boss 32 is aligned with the central axis of the corresponding through hole (not shown) provided in the protruding piece 21B of the casing 21 of the external environment sensor 14.

The external environment sensor 14 may be fastened to the base 18 by bolts 35 (see FIG. 4). For example, each bolt 35 penetrates through the through hole (not shown) of the protruding piece 21B of the casing 21 of the external environment sensor 14 and screws into the female screw of the boss 32.

The position sensor 15 is fixed to the base rear portion 28. The base rear portion 28 extends horizontally. A plurality of fastening holes (not shown) that penetrates through the base rear portion 28 in the up-and-down direction is formed in the base rear portion 28. A female screw (not shown) may be formed in each fastening hole of the base rear portion 28. Each fastening hole of the base rear portion 28 is aligned with the central axis of the corresponding through hole (not shown) provided in the protruding piece 23B of the casing 23 of the position sensor 15.

The position sensor 15 may be fastened to the base 18 by bolts 36 (see FIG. 4). For example, each bolt 36 penetrates through the through hole (not shown) of the protruding piece 23B of the casing 23 of the position sensor 15 and screws into the female screw of the base rear portion 28.

The base rear portion 28 includes an insertion hole 37 penetrating in the up-and-down direction and a grommet 38 inserted into the insertion hole 37. The harness 22 of the external environment sensor 14 passes through the insertion hole 37 of the base 18 via the grommet 38. The harness 22 of the external environment sensor 14 is connected to the controller 16.

The step 30 extends in the up-and-down direction. The upper end of the step 30 is connected to the front end of the base rear portion 28. The lower end of the step 30 is connected to the rear end of the base front portion 26.

In the present embodiment, the roof rail 19 has the main surface facing upward. The roof rail 19 is arranged between the left and right side rails 4. Further, the roof rail 19 is arranged between the roof panel 6 and the windshield 8. That is, the portion of each side rail 4 from the roof rail 19 to the hood 9 extends forward with a downward inclination. The roof rail 19 may be arranged, for example, above the roof member 5. The upper surface of the roof rail 19 is arranged lower than the upper surface of the roof panel 6.

As shown in FIGS. 4, 6 and 7, the roof rail 19 includes a first inclined portion 41 that extends forward with a downward inclination, and a pair of second inclined portions 42 that extends laterally outward with a downward inclination from the first inclined portion 41. The first inclined portion 41 continues from the rear end of the roof rail 19 to the front end thereof. Of the pair of second inclined portions 42, one second inclined portion 42 extends leftward with a downward inclination from the central portion in the lateral direction of the roof rail 19. Of the pair of second inclined portions 42, the other second inclined portion 42 extends rightward with a downward inclination from the central portion in the lateral direction of the roof rail 19.

The front end of the first inclined portion 41, i.e., the front end of the roof rail 19, is connected to the upper end of the windshield 8. The laterally outward end of each second inclined portion 42, i.e., the lateral end of the roof rail 19, is connected to the corresponding side rail 4.

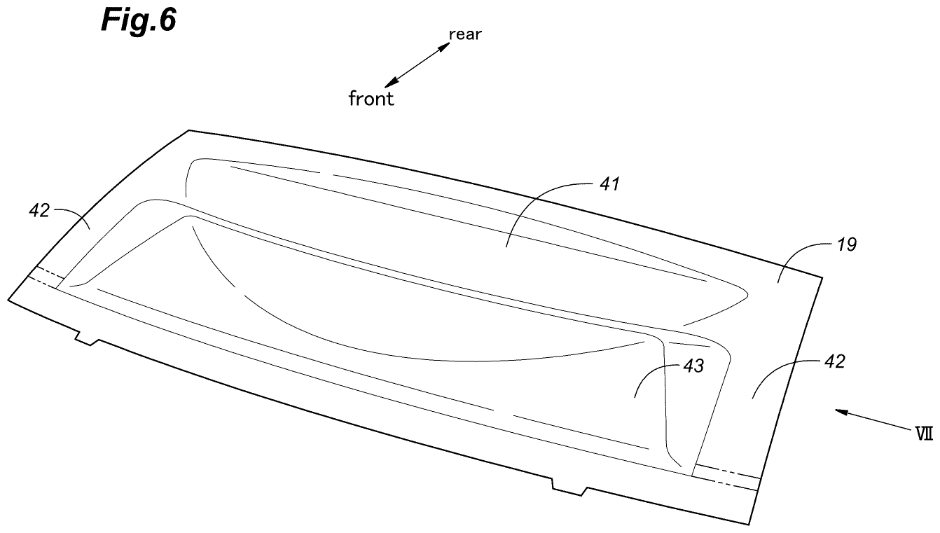

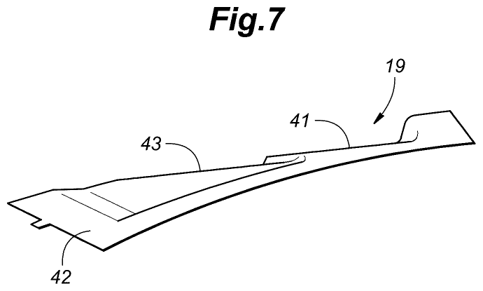

As shown in FIGS. 6 and 7, a recessed portion 43 that is recessed downward is formed on the upper surface of the roof rail 19. The recessed portion 43 is provided in the front portion of the roof rail 19. The recessed portion 43 is provided across the first inclined portion 41 and the second inclined portions 42. The external environment sensor 14 is arranged above the recessed portion 43 with the base front portion 26 therebetween.

As shown in FIGS. 3 to 5, the cover 20 is formed in a plate shape. The cover 20 is arranged above the base 18 and the roof rail 19. A bulging portion 45 bulging upward is provided in the central portion of the cover 20 in the lateral direction. The upper surfaces of the left and right side portions of the cover 20 are arranged on the same plane as the upper surface of the roof panel 6 and the upper surface of the windshield 8.

The bulging portion 45 of the cover 20 includes a front wall 46 arranged in front of the external environment sensor 14, a rear wall 47 arranged behind the external environment sensor 14, a pair of sidewalls 48 connecting the left and right ends of the front wall 46 and the corresponding left and right ends of the rear wall 47, and an upper wall 49 connecting the upper end of the front wall 46, the upper end of the rear wall 47 and the upper end of each sidewall 48. The external environment sensor 14 and the position sensor 15 are arranged in the internal space of the bulging portion 45 of the cover 20, i.e., a space 51 (internal space) defined by the front wall 46, the rear wall 47, each sidewall 48 and the upper wall 49.

The front wall 46 extends forward with a downward inclination. The front wall 46 is provided with an opening 52 and a first air flow opening 53 that connects the internal space of the cover 20 and the external space thereof. The opening 52 overlaps with the front surface of the external environment sensor 14 when viewed from the front. The opening 52 is provided with a panel material 54. The panel material 54 may be formed, for example, from a transparent or translucent resin material.

The first air flow opening 53 is formed in a rectangular shape elongated in the lateral direction. The width of the first air flow opening 53 in the lateral direction is substantially equal to the width of the opening 52 in the lateral direction. The first air flow opening 53 is formed above the opening 52.

The rear wall 47 extends rearward with a downward inclination. The rear wall 47 is provided with a second air flow opening 55 that connects the internal space of the cover 20 and the external space thereof. The second air flow opening 55 is formed in a rectangular shape elongated in the lateral direction. The second air flow opening 55 is provided in the upper portion of the rear wall 47. The second air flow opening 55 may overlap with at least a portion of the first air flow opening 53 when viewed in the front-and-rear direction.

As shown in FIG. 5, the internal space of the bulging portion 45 of the cover 20 is provided with an air flow passage 57 that connects the first air flow opening 53 and the second air flow opening 55. The air flow passage 57 extends along the front-and-rear direction from the first air flow opening 53 to the second air flow opening 55. The air flow passage 57 forms a portion of the internal space 51 of the bulging portion 45 of the cover 20. In the present embodiment, the air flow passage 57 is the space between the upper wall 49 of the bulging portion 45 and the external environment sensor 14, within the internal space 51 of the bulging portion 45 of the cover 20. That is, the air flow passage 57 is arranged above the external environment sensor 14.

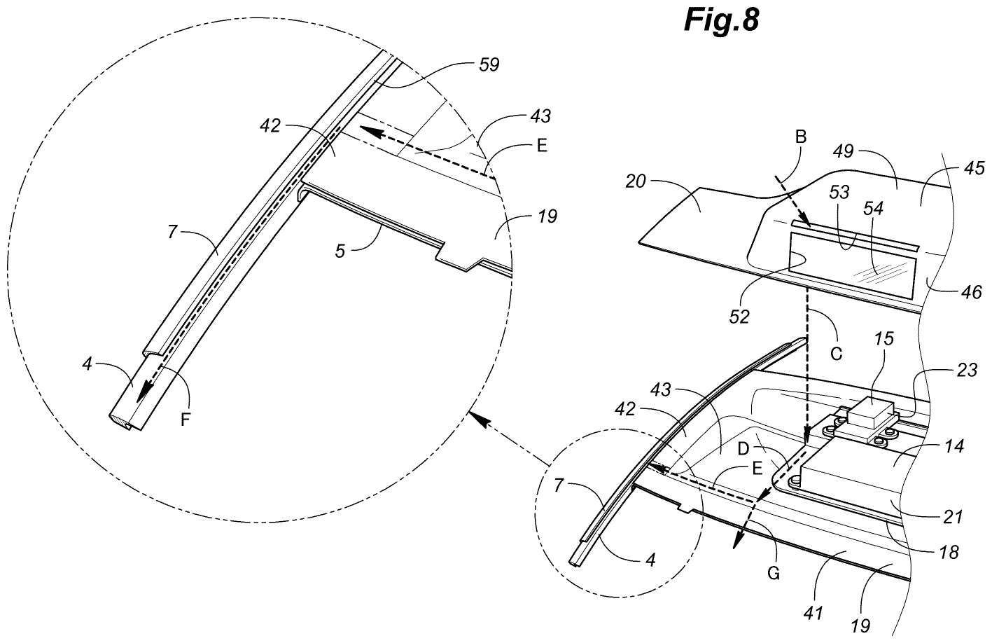

As shown in FIGS. 3 and 8, each of the left and right side rails 4 defines a groove 59 that continues from the laterally outward space of the roof rail 19 to the hood 9. The groove 59 is defined by the side rail 4, the side garnish 7, the roof rail 19 and the windshield 8. For example, the laterally outward end of the second inclined portion 42 of the roof rail 19 and the lateral end of the windshield 8 face the upper edge of the laterally corresponding side garnish 7 above the side rail 4 with a gap therebetween. In the present embodiment, this gap forms the groove 59. That is, the laterally outward end of the second inclined portion 42 of the roof rail 19 is connected to the groove 59.

In another embodiment, the groove 59 may be provided along the extending direction of the side rail 4 so as to be recessed downward from the upper surface of the side rail 4.

By arranging the external environment sensor 14 on the upper structure 2 (roof) of the vehicle 1, interference (vignetting) of the exterior members of the vehicle 1 with the detection range of the external environment sensor 14 is suppressed compared to a case where the external environment sensor 14 is arranged on the front structure 3 of the vehicle 1 (for example, the exterior members such as the front bumper 12). Furthermore, since the external environment sensor 14 is arranged at a higher position compared to a case where the external environment sensor 14 is arranged on the front structure 3 of the vehicle 1, it is possible to prevent mud, snow, and the like kicked up by other vehicles in front of the vehicle 1 from adhering to the external environment sensor 14. Further, since the external impact due to a light collision and the like is unlikely to be transmitted, damage to the external environment sensor 14 is suppressed.

The action and effect of the sensor attachment structure 17 configured as described above will now be described.

The controller 16 is configured to determine whether the vehicle 1 is stopped based on the detection result of the vehicle speed sensor 13. For example, when the vehicle speed detected by the vehicle speed sensor 13 is 0, the controller 16 may determine that the vehicle 1 is stopped. In a case where the controller 16 determines that the vehicle 1 is stopped for the prescribed period, the controller 16 stops operation of the external environment sensor 14.

As shown in FIG. 5, the first air flow opening 53 and the second air flow opening 55 connect the internal space of the bulging portion 45 of the cover 20 to the external space thereof. Accordingly, for example, when the vehicle 1 is traveling forward, the travel wind caused by the traveling of the vehicle 1 passes through the air flow passage 57 from the front to the rear (arrow A). The travel wind passing through the air flow passage 57 cools the internal space of the cover 20, more specifically, the external environment sensor 14 (LiDAR) arranged in the internal space 51 of the bulging portion 45, and the circumference of the external environment sensor 14. This suppresses the increase in the ambient temperature of the external environment sensor 14 (LiDAR) in the sensor attachment structure 17 arranged on the upper structure 2 (roof) of the vehicle 1, thereby suppressing the thermal load on the external environment sensor 14. Since the air flow passage 57 extends from the first air flow opening 53 to the second air flow opening 55 along the front-and-rear direction, the travel wind passes through the air flow passage 57 smoothly along the front-and-rear direction. Accordingly, the cooling effect on the external environment sensor 14 and the circumference thereof can be improved.

In a case where the controller 16 determines that the vehicle 1 is stopped for the prescribed period, the controller 16 stops operation of the external environment sensor 14. Accordingly, it is possible to suppress the heat generation of the external environment sensor 14 when the vehicle 1 is stopped and the travel wind is not blowing. Accordingly, the increase in the ambient temperature of the external environment sensor 14 is more effectively suppressed.

As shown in FIG. 8, due to rainfall and the like, water enters the internal space of the cover 20 from the external space through the first air flow opening 53 or the second air flow opening 55 (arrow B). The water that has entered from the external space falls down toward the roof rail 19 (arrow C). The first inclined portion 41 of the roof rail 19 continues from the rear end to the front end of the roof rail 19. That is, the first inclined portion 41 continues from a space below the second air flow opening 55 to a space below the first air flow opening 53. Accordingly, the water on the roof rail 19 is drained along the first inclined portion 41 to the front side of the roof rail 19 (arrow D). A portion of the water drained to the front side of the roof rail 19 along the first inclined portion 41 is drained to the laterally outward space of the roof rail 19 along the second inclined portion 42 (arrow E). The lateral end of the roof rail 19, more specifically, the laterally outward end of the second inclined portion 42 of the roof rail 19 is connected to the groove 59 of the laterally corresponding side rails 4. Accordingly, the water drained to the laterally outward space along the second inclined portion 42 is drained forward of the roof rail 19 along the groove 59 of the side rail 4, more specifically, drained onto the hood 9 (see FIG. 1) (arrow F). These features make it possible to prevent water that has entered the internal space of the cover 20 from the external space through the first air flow opening 53 or the second air flow opening 55 from accumulating on the circumference of the external environment sensor 14.

Since the laterally outward end of each second inclined portion 42 is connected to the corresponding side rail 4, the water drained to the laterally outward space of the roof rail 19 through each second inclined portion 42 can be prevented from flowing back to each second inclined portion 42. Further, the groove 59 in the side rail 4 ensures that the water drained from the roof rail 19 is drained in the appropriate direction (onto the hood 9) without being drained from the left and right sides of the vehicle 1.

The front end of the roof rail 19 is connected to the upper end of the windshield 8. Accordingly, the water drained along the first inclined portion 41 to the front side of the roof rail 19 is drained onto the windshield 8 (arrow G). Accordingly, the water drained to the front of the cover 20 through the first inclined portion 41 can be prevented from flowing back to the first inclined portion 41.

When the vehicle 1 travels uphill, the vehicle 1 inclines upward toward the front. At this time, the roof rail 19 may also incline upward toward the front. In this case, water that has entered the internal space of the cover 20 from the external space is drained rearward along the upper surface of the roof rail 19, more specifically, toward the recessed portion 43 of the roof rail 19. The water drained toward the recessed portion 43 of the roof rail 19 is drained laterally outward along the second inclined portion 42. In this way, even if the roof rail 19 inclines upward toward the front, the water drained to the laterally outward space of the roof rail 19 through each second inclined portion 42 can be prevented from flowing back to each second inclined portion 42. Accordingly, even if the roof rail 19 inclines upward toward the front, the water, which has entered the internal space of the cover 20 from the external space through the first air flow opening 53 or the second air flow opening 55, can be reliably prevented from accumulating on the circumference of the external environment sensor 14.

Concrete embodiments of the present invention have been described in the foregoing, but the present invention should not be limited by the foregoing embodiments and various modifications and alterations are possible within the scope of the present invention. For example, in the embodiment described above, the first air flow opening 53 is provided above the opening 52, but the first air flow openings 53 may be provided on the left and right sides of the opening 52. Furthermore, although the LiDAR is an example of the external environment sensor 14 in the embodiment described above, a sensor other than the LiDAR (for example, a millimeter wave radar, a microwave radar, or an ultrasonic sensor) may be an example of the external environment sensor 14 in another embodiment.

1. An attachment structure of an external environment sensor arranged on a roof of a vehicle, the attachment structure comprising:
an external environment sensor;
a mounting portion on which the external environment sensor is mounted; and
a cover arranged over the external environment sensor,
wherein a front portion of the cover is provided with a first air flow opening that connects an internal space of the cover and an external space of the cover,
a rear portion of the cover is provided with a second air flow opening that connects the internal space of the cover and the external space of the cover, and
the internal space of the cover is provided with an air flow passage that connects the first air flow opening and the second air flow opening.

2. The attachment structure of the external environment sensor according to claim 1, wherein the mounting portion is a roof rail having a main surface facing upward,
the roof rail includes a first inclined portion that extends forward with a downward inclination, and
the first inclined portion continues from a space below the second air flow opening to a space below the first air flow opening.

3. The attachment structure of the external environment sensor according to claim 2, wherein the roof rail further includes a pair of second inclined portions that extends laterally outward with a downward inclination from the first inclined portion.

4. The attachment structure of the external environment sensor according to claim 3, wherein the vehicle further includes a pair of side rails that extends forward with a downward inclination from a laterally outward space of the roof rail to a hood of the vehicle, and
a laterally outward end of each of the second inclined portions is connected to the corresponding side rail.

5. The attachment structure of the external environment sensor according to claim 4, wherein each of the side rails defines a groove that continues from the laterally outward space of the roof rail to the hood, and
the laterally outward end of each of the second inclined portions is connected to the groove.

6. The attachment structure of the external environment sensor according to claim 2, wherein a front end of the first inclined portion is connected to an upper end of a windshield of the vehicle.

7. The attachment structure of the external environment sensor according to claim 1, wherein the air flow passage extends along a front-and-rear direction from the first air flow opening to the second air flow opening.

8. The attachment structure of the external environment sensor according to claim 1, wherein the external environment sensor is a LiDAR.

9. A vehicle, comprising:
the attachment structure of the external environment sensor according to claim 1;
a vehicle speed sensor configured to detect a vehicle speed; and
a controller connected to the external environment sensor and the vehicle speed sensor,
wherein the controller is configured to
determine whether the vehicle is stopped based on a detection result of the vehicle speed sensor, and
stop operation of the external environment sensor in a case where the controller determines that the vehicle is stopped.
